(19) United States
(12) Patent Application Publication
(10) Pub. No.: US 2025/0072061 A1
(43) Pub. Date: Feb. 27, 2025

(54) SEMICONDUCTOR DEVICE WITH DECREASED SOURCE AND DRAIN RESISTANCE AND MANUFACTURING METHOD

(71) Applicant: INSTITUTE OF MICROELECTRONICS, CHINESE ACADEMY OF SCIENCES, Beijing (CN)

(72) Inventors: Zijin YAN, Beijing (CN); Huilong ZHU, Poughkeepsie, NY (US)

(21) Appl. No.: 18/650,805

(22) Filed: Apr. 30, 2024

(30) Foreign Application Priority Data
Aug. 21, 2023 (CN) 202311051884.9

(51) Int. Cl. H01L 29/06; H01L 21/762; H01L 27/02; H01L 27/092; H01L 29/08; H01L 29/10; H01L 29/161

(52) U.S. Cl. CPC H01L 29/0603; H01L 21/76224; H01L 27/0207; H01L 27/092; H01L 29/0847; H01L 29/1033; H01L 29/161

(57) ABSTRACT

Provided are a semiconductor device with decreased source and drain resistance and a manufacturing method. The semiconductor device includes a substrate and multiple three-dimensional semiconductor device arrays. The three-dimensional semiconductor device arrays are on the substrate, and the three-dimensional semiconductor device arrays are separated by isolation grooves. Each three-dimensional semiconductor device array includes a plurality of device layers in a vertical direction, each device layer includes a stack of a source/drain layer, a channel layer and a source/drain layer, and an end face of the source/drain layer adjacent to the isolation groove is metallized. The three-dimensional semiconductor device array further includes a plurality of gate stacks arranged in an array, the gate stack penetrates each device layer in the vertical direction and includes a gate material and a gate dielectric layer, and a device unit is defined at an intersection of the gate stack and the device layer.

### CROSS REFERENCE TO RELATED APPLICATION

This application claims priority to Chinese Patent Application No. 202311051884.9, filed on Aug. 21, 2023, the entire content of which is incorporated herein in its entirety by reference.

### TECHNICAL FIELD

The present disclosure relates to a field of semiconductor technology, in particular to a semiconductor device with decreased source and drain resistance and a manufacturing method.

### BACKGROUND

With the development of the integrated circuit industry, three-dimensional semiconductor devices have become a hot research direction due to their excellent integration. A source/drain/channel and a gate dielectric and gate above the channel serve as a basic structure of an MOS transistor. One method for achieving a three-dimensional device is to stack the source/channel/drain in a vertical direction, and a space to form the gate dielectric and gate is reserved by digging holes or forming grooves.

However, the stacking of the device in the vertical direction also brings difficulty in leading out a device at the center of a three-dimensional device array (such as the Chinese patent, Pub. No. CN112909011A). Heavily doped silicon has a high resistivity, and thus when leading out the source and drain at the center of the device array using heavily doped silicon connection, a problem of large source and drain resistance emerges, which further leads to a decrease in the consistency of device characteristics in the array, and may even cause errors in use.

### SUMMARY

The present disclosure provides a semiconductor device with decreased source and drain resistance and a manufacturing method.

In an aspect, the present disclosure provides a semiconductor device with decreased source and drain resistance, including: a substrate and a plurality of three-dimensional semiconductor device arrays. The three-dimensional semiconductor device arrays are provided on the substrate, and the three-dimensional semiconductor device arrays are separated by isolation grooves. Each of the three-dimensional semiconductor device arrays includes a plurality of device layers in a vertical direction, each of the device layers includes a stack of a source/drain layer, a channel layer and a source/drain layer, and an end face of the source/drain layer adjacent to the isolation groove is metallized to form a silicide. The three-dimensional semiconductor device array further includes a plurality of gate stacks arranged in an array, where the gate stack penetrates each of the device layers in the vertical direction and includes a gate material and a gate dielectric layer provided between the gate material and the device layer, and a device unit is defined at an intersection of the gate stack and the device layer.

According to an embodiment of the present disclosure, the source/drain layer and the channel layer in each of the device layers extend in a direction in which the isolation groove extends, and a staircase like contact region is formed at the source/drain layer.

According to an embodiment of the present disclosure, a silicon dioxide is deposited on the three-dimensional semiconductor device array to form a dielectric isolation layer which covers a contact region and an upper surface of the three-dimensional semiconductor device array as well as each isolation groove, and an upper surface of the dielectric isolation layer is flattened by chemical mechanical polishing.

According to an embodiment of the present disclosure, vertically etching is performed downwards from the upper surface of the dielectric isolation layer to form a plurality of contact holes, and each of the contact holes extends to the contact region of the source/drain layer.

According to an embodiment of the present disclosure, a lower source/drain layer in an upper device layer and an upper source/drain layer in a lower device layer adjacent to the upper device layer are the same source/drain layer.

According to an embodiment of the present disclosure, a silicon dioxide isolation layer is provided between source/drain layers of each two device layer in the three-dimensional semiconductor device array and at a bottom of the three-dimensional semiconductor device array; a bottom of the gate stack is located in the silicon dioxide isolation layer at the bottom of the three-dimensional semiconductor device array; and the channel layer is provided between the gate dielectric layer and a structure formed by the two source/drain layers and the silicon dioxide isolation grooves.

According to an embodiment of the present disclosure, each of the source/drain layer and the channel layer is made of a doped polycrystalline silicon material.

According to an embodiment of the present disclosure, an upper surface of the substrate is provided with a silicon germanium layer; a bottom of the gate stack is located in the silicon germanium layer; the source/drain layer, the channel layer and the source/drain layer in the device layer are stacked sequentially from bottom to top; a bottom of the isolation groove is located in the silicon germanium layer; and a dielectric inner spacer is formed at each of an end face of the channel layer adjacent to the isolation groove and an end face of the silicon germanium layer adjacent to the isolation groove.

According to an embodiment of the present disclosure, the source/drain layer is made of an N-type doped silicon material, and the channel layer is made of a P-type silicon germanium material.

In another aspect, the present disclosure provides a manufacturing method, including: growing a plurality of device layers on a substrate, wherein each of the device layers includes a stack of a source/drain layer, a channel layer and a source/drain layer; forming a plurality of gate holes penetrating each of the device layers in a vertical direction perpendicular to the substrate, and forming gate stacks in the gate holes, the gate stacks being arranged in an array, where the gate stack includes a gate material and a gate dielectric layer provided between the gate material and the device layer, and a device unit is defined at an intersection of the gate stack and the device layer; etching the device layer in the vertical direction perpendicular to the substrate, so as to form isolation grooves and a plurality of three-dimensional semiconductor device arrays separated by the isolation grooves; and metallizing an end face of the source/drain layer in each of the three-dimensional semiconductor device arrays adjacent to the isolation groove to form a silicide.

### BRIEF DESCRIPTION OF THE DRAWINGS

In order to have a more complete understanding of the present disclosure and its advantages, the following description of the accompanying drawings will be referred to and combined with, in which:

FIG. 1A schematically shows a top view of a semiconductor device with decreased source and drain resistance provided in embodiments of the present disclosure;

FIG. 1B schematically shows a sectional view of a semiconductor device with decreased source and drain resistance provided in embodiments of the present disclosure in AA′ direction;

FIG. 2A schematically shows a sectional view of a device layer stack of a semiconductor device with decreased source and drain resistance provided in a second embodiment of the present disclosure;

FIG. 2B schematically shows a top view of gate stacks, arranged in an array, of a semiconductor device with decreased source and drain resistance provided in the second embodiment of the present disclosure;

FIG. 2C schematically shows a sectional view of etching gate holes of gate stacks in a semiconductor device with decreased source and drain resistance provided in the second embodiment of the present disclosure in BB′ direction;

FIG. 2D schematically shows a sectional view of forming gate stacks of a semiconductor device with decreased source and drain resistance provided in the second embodiment of the present disclosure in BB′ direction;

FIG. 2E schematically shows a top view of etching isolation grooves in a semiconductor device with decreased source and drain resistance provided in the second embodiment of the present disclosure;

FIG. 2F schematically shows a sectional view of a semiconductor device with decreased source and drain resistance provided in the second embodiment of the present disclosure in AA′ direction;

FIG. 2G schematically shows a schematic diagram of silicidation of side surfaces of a semiconductor device with decreased source and drain resistance provided in the second embodiment of the present disclosure;

FIG. 2H schematically shows a sectional view of a filling dielectric of a semiconductor device with decreased source and drain resistance provided in the second embodiment of the present disclosure in AA′ direction;

FIG. 2I schematically shows a top view of a semiconductor device with decreased source and drain resistance provided in the second embodiment of the present disclosure;

FIG. 2J schematically shows a sectional view of a contact region of a semiconductor device with decreased source and drain resistance provided in the second embodiment of the present disclosure in CC′ direction;

FIG. 2K schematically shows a schematic diagram of contact holes of a semiconductor device with decreased source and drain resistance provided in the second embodiment of the present disclosure;

FIG. 3A schematically shows a sectional view of a device layer stack of a semiconductor device with decreased source and drain resistance provided in a third embodiment of the present disclosure;

FIG. 3B schematically shows a top view of gate stacks, arranged in an array, of a semiconductor device with decreased source and drain resistance provided in the third embodiment of the present disclosure;

FIG. 3C schematically shows a sectional view of etching gate holes of the gate stacks in a semiconductor device with decreased source and drain resistance provided in the third embodiment of the present disclosure in BB′ direction;

FIG. 3D schematically shows a sectional view of forming the gate stacks of a semiconductor device with decreased source and drain resistance provided in the third embodiment of the present disclosure in BB′ direction;

FIG. 3E schematically shows a top view of etching isolation grooves in a semiconductor device with decreased source and drain resistance provided in the third embodiment of the present disclosure;

FIG. 3F schematically shows a sectional view of a semiconductor device with decreased source and drain resistance provided in the third embodiment of the present disclosure in AA′ direction after the isolation grooves are etched;

FIG. 3G schematically shows a schematic diagram of etching a source/drain layer of a semiconductor device with decreased source and drain resistance provided in the third embodiment of the present disclosure;

FIG. 3H schematically shows a schematic diagram of forming dielectric inner spacers of a semiconductor device with decreased source and drain resistance provided in the third embodiment of the present disclosure;

FIG. 3I schematically shows a schematic diagram of silicidation of side surfaces of a semiconductor device with decreased source and drain resistance provided in the third embodiment of the present disclosure;

FIG. 3J schematically shows a sectional view of a filling dielectric of a semiconductor device with decreased source and drain resistance provided in the third embodiment of the present disclosure in AA′ direction;

FIG. 3K schematically shows a top view of a semiconductor device with decreased source and drain resistance provided in the third embodiment of the present disclosure;

FIG. 3L schematically shows a sectional view of a contact region of a semiconductor device with decreased source and drain resistance provided in the third embodiment of the present disclosure in CC′direction; and

FIG. 3M schematically shows a schematic diagram of contact holes of a semiconductor device with decreased source and drain resistance provided in the third embodiment of the present disclosure.

### REFERENCES SIGNS

1—substrate; 2—three—dimensional semiconductor device array; 21—silicon dioxide isolation layer; 22—source/drain layer; 23—channel layer; 24—silicon germanium layer; D1—device layer; 3—isolation groove; 4—gate stack; 41—gate material; 42—gate dielectric layer; 5—silicide; 6—dielectric isolation layer; 7—contact hole; 8—dielectric inner spacer; and 81—dielectric inner spacer recess.

### DETAILED DESCRIPTION OF EMBODIMENTS

Embodiments of the present disclosure will be described below with reference to the accompanying drawings. However, it will be understood that these descriptions are only illustrative and are not intended to limit the scope of the present disclosure. In the following detailed description, for ease of introduction, various specific details are elaborated to provide a comprehensive understanding of embodiments of the present disclosure. However, it is evident that one or more embodiments may also be implemented without these specific details. In addition, in the following introduction, descriptions of well-known structures and techniques are omitted to avoid unnecessary confusion with concepts of the present disclosure.

The terms used herein are only intended to describe specific embodiments and are not intended to limit the present disclosure. The terms “including”, “containing”, etc. used herein indicate the existence of the features, steps, operations, and/or components, but do not exclude the existence or addition of one or more other features, steps, operations, or components.

All terms used herein (including technical and scientific terms) have the meanings commonly understood by those skilled in the art, unless otherwise defined. It will be noted that the terms used herein should be interpreted as having a meaning consistent with the context of the present disclosure, and should not be interpreted in an idealized or overly rigid manner.

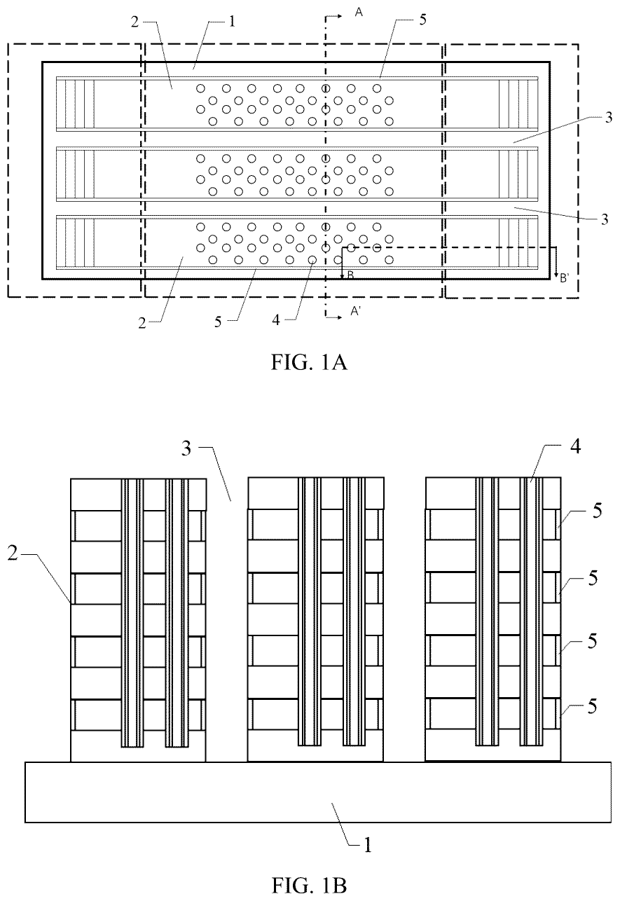

FIG. 1A schematically shows a top view of a semiconductor device with decreased source and drain resistance provided in embodiments of the present disclosure.

As shown in FIG. 1A, in embodiments of the present disclosure, a semiconductor device with decreased source and drain resistance includes a substrate 1 and a plurality of three-dimensional semiconductor device arrays 2. The three-dimensional semiconductor device arrays 2 are provided on the substrate 1, and the respective three-dimensional semiconductor device arrays 2 are separated by isolation grooves 3. Separating devices in the arrays by the isolation grooves 3 may help to lead out the devices and reduce disturbance between the devices.

FIG. 1B schematically shows a sectional view of a semiconductor device with decreased source and drain resistance provided in embodiments of the present disclosure in AA′ direction.

As shown in FIG. 1B, in embodiments of the present disclosure, each three-dimensional semiconductor device array 2 includes a plurality of device layers in a vertical direction. Each device layer includes a stack of a lower source/drain layer, a channel layer and an upper source/drain layer, and an end face of the source/drain layer adjacent to the isolation groove 3 is metallized, so as to form a silicide 5. In addition, for simplicity of the manufacturing process, a bottom of the isolation groove 3 is also metallized during the process of metalizing the end face of the source/drain layer.

Referring to FIGS. 1A and 1B, the three-dimensional semiconductor device array 2 further includes a plurality of gate stacks 4 arranged in an array. The gate stack 4 penetrates each device layer in the vertical direction and includes a gate material 41 and a gate dielectric layer 42 provided between the gate material 41 and the device layer. A device unit is defined at an intersection of the gate stack 4 and the device layer. Applying a voltage on the gate stack 4 may control programming and erasing. At opposite ends of each three-dimensional semiconductor device array 2, the source/drain layer and the channel layer 23 in each device layer extend in a direction in which the isolation groove 3 extends. A staircase like contact region is formed at each source/drain layer for forming a lead-out structure for each layer (source/drain layer and body layer).

Compared with related vertically stacked semiconductor devices, in the semiconductor device provided by embodiments of the present disclosure, the end face of the source/drain layer adjacent to the isolation groove 3 is metallized. Since a resistivity of a metalized structure is much lower than a resistivity of silicon, the problem of large source and drain resistance may be effectively solved using a feasible formation method.

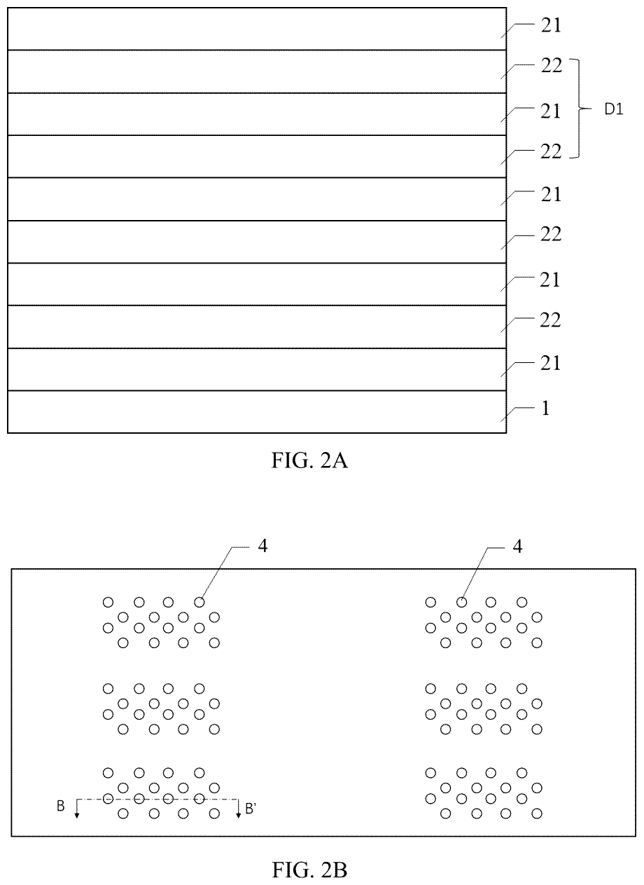

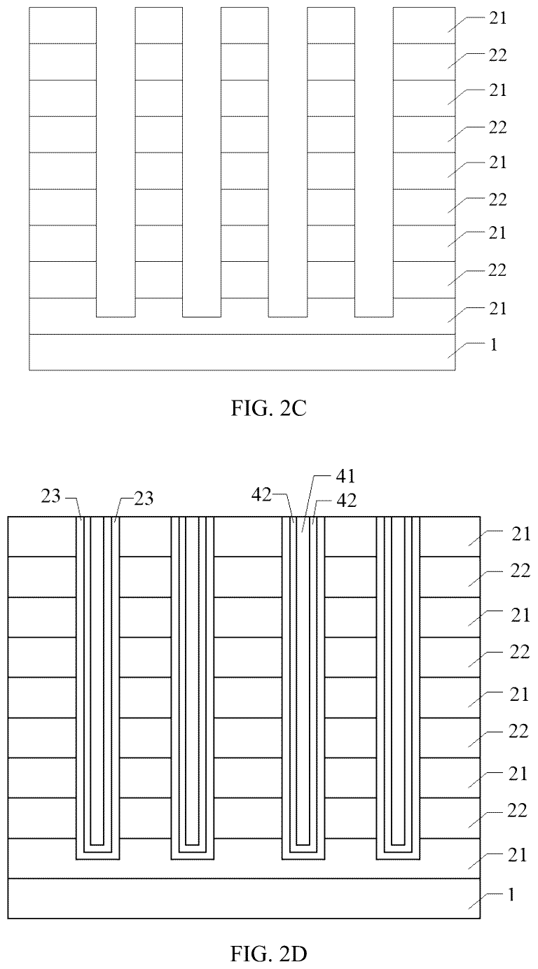

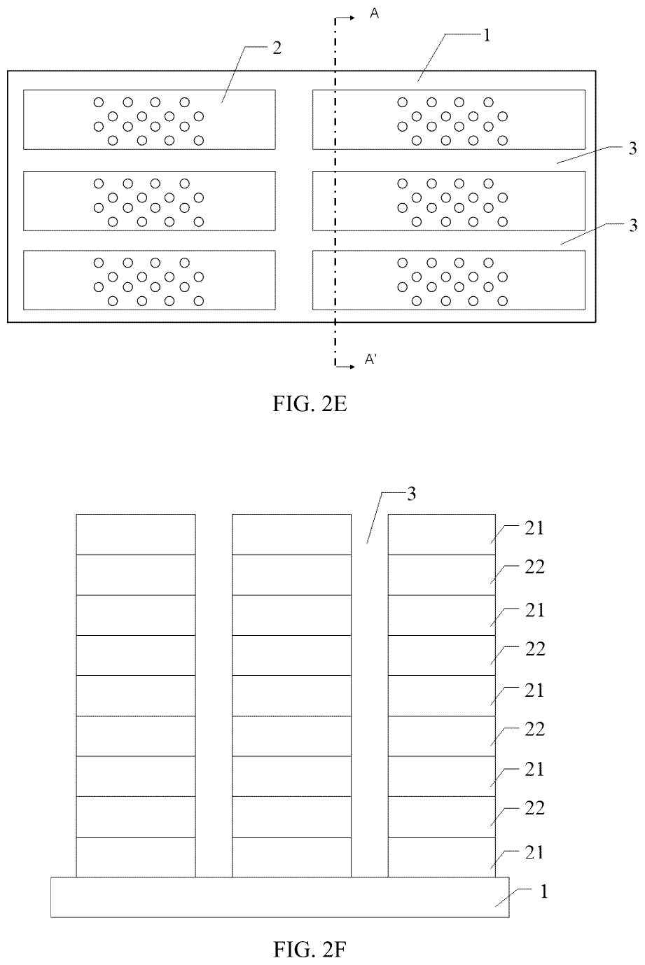

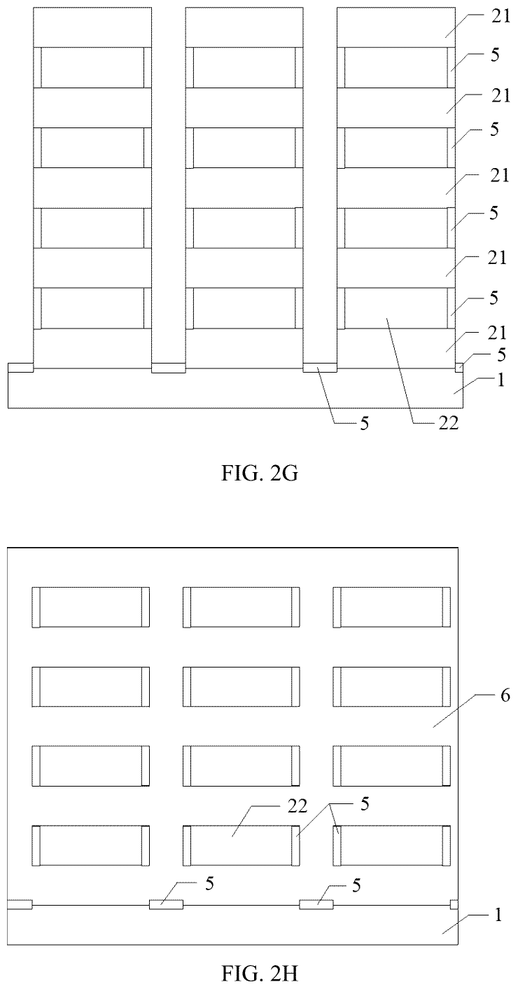

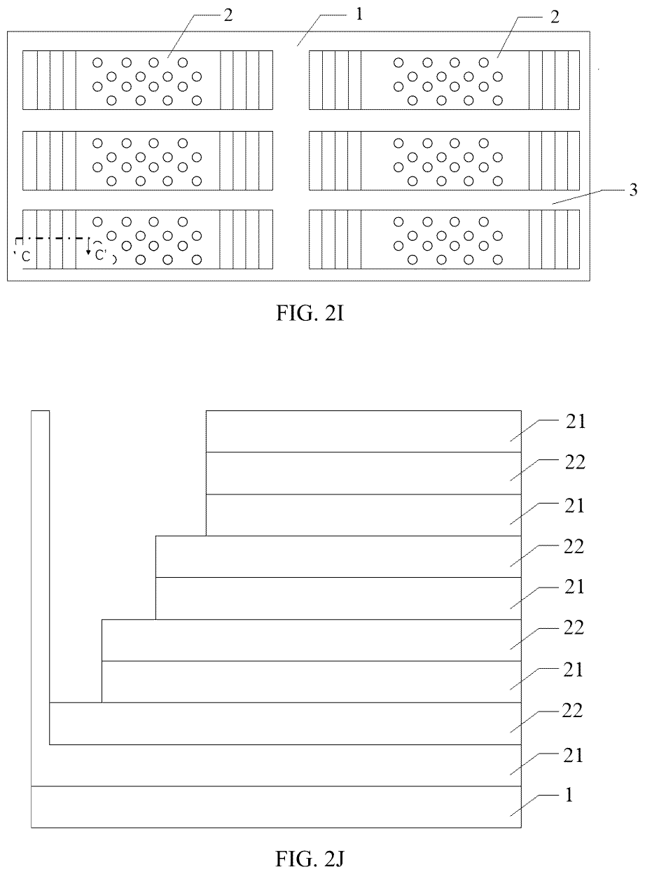

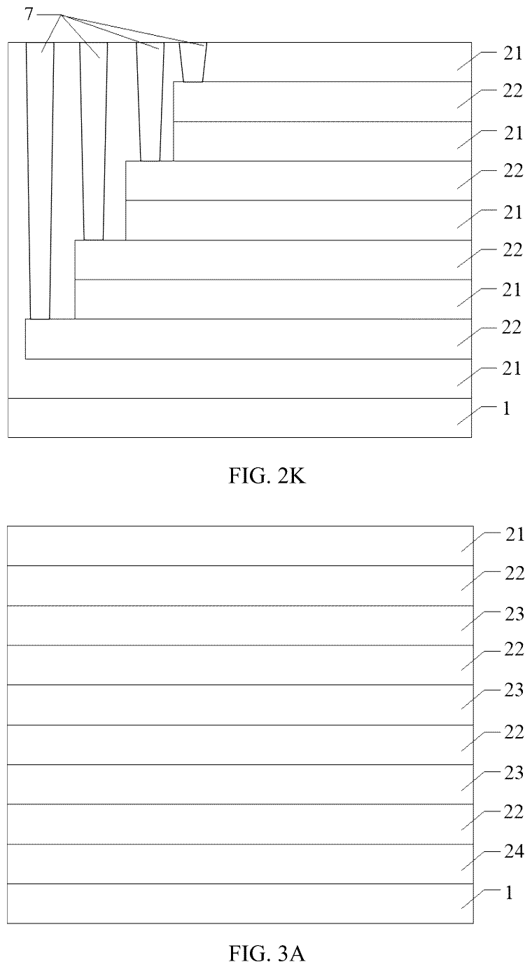

A second embodiment of the present disclosure provides a semiconductor device with decreased source and drain resistance, specific structures of which are schematically shown in FIGS. 2A to 2K, where a manufacturing process of the semiconductor device is also represented.

As shown in FIG. 2A, in the second embodiment of the present disclosure, the substrate 1 may be a substrate in various forms, including but not limited to a bulk semiconductor material substrate such as a bulk Si substrate, a semiconductor on insulator (SOI) substrate, a compound semiconductor substrate such as a GaAs substrate, etc. A plurality of device layers D1 are grown on the substrate 1. In a device layer D1, source/drain layers 22 are made of doped polysilicon, a silicon dioxide layer is provided between an upper source/drain layer 22 and a lower source/drain layer 22, and a channel layer 23 is to be formed in subsequent processes. The lower source/drain layer 22 of an upper device layer and the upper source/drain layer 22 of a lower device layer which is adjacent to the upper device layer may be the same source/drain layer. By sharing the same source/drain layer, a size of the device may be reduced and the manufacturing process may be simplified. Each of a top of a top device layer in the three-dimensional semiconductor device array 2 and a bottom of the three-dimensional semiconductor device array 2 is provided with a silicon dioxide isolation layer. FIG. 2A merely schematically shows three device layers stacked together, however, in practical operations, device layers may be stacked infinitely upwards until the techniques cannot support it (one device layer is defined by two adjacent layers of polysilicon). In this example, the device manufactured may be an NMOS device, and this method may also be used to form a PMOS device or an NOR flash. A thickness of doped polysilicon may be in a range of 10 nm to 500 nm, and a thickness of silicon dioxide may be in a range of 5 nm to 500 nm.

As shown in FIG. 2B, the respective device layers are penetrated in a vertical direction perpendicular to the substrate 1, so as to form a plurality of gate holes. The gate holes may be formed by etching the layers on the substrate 1 using a photoresist as an etching mask through an anisotropic etching process, such as a reactive ion etching (RIE) process. Gate stacks 4 are formed in the gate holes, and the gate stacks 4 are arranged in an array. The gate stack 4 includes a gate material 41 and a gate dielectric layer 42 which is provided between the gate material 41 and the device layer. A device unit is defined at an intersection of the gate stack 4 and the device layer. The gate material 41 may include a conductor material and a semiconductor material.

FIG. 2C shows a sectional view of an array of gate stacks 4 shown in FIG. 2B in BB′ direction. The respective device layers are penetrated in the vertical direction to form the plurality of gate holes. The etching of the gate holes stops when reaching silicon dioxide at the bottom.

As shown in FIG. 2D, polysilicon is deposited in the gate holes, and in-situ doping or injection may be used to adjust a concentration of channel impurities. A channel layer 23 is formed both on a sidewall of the gate hole and at a bottom of the gate hole, that is, the channel layer 23 is provided between the gate dielectric layer 42 and a structure composed of the upper source/drain layer 22, the silicon dioxide isolation layer and the lower source/drain layer 22. For the convenience of process implementation, the channel layer 23 is also grown between a bottom of the gate dielectric layer 42 and a silicon dioxide isolation layer which is at a bottom of the three-dimensional semiconductor device array 2 during a growth process. Then, the gate dielectric layer 42 is deposited in the gate hole. Finally, the gate material 41 is deposited, and a top of the device is flattened by chemical mechanical polishing. A bottom of the gate stack 4 is in the silicon dioxide isolation layer which is at the bottom of the three-dimensional semiconductor device array 2.

As shown in FIG. 2E, after the array of the gate stacks 4 is manufactured, the device layers are etched in the vertical direction perpendicular to the substrate 1, so as to form the isolation groove 3 and the plurality of three-dimensional semiconductor device arrays 2 which are separated by the isolation groove 3. FIG. 2F schematically shows a sectional view in AA′ direction after etching out the isolation groove 3, from which it may be seen that the etching of the isolation groove 3 stops immediately when reaching the substrate 1, so that the respective three-dimensional semiconductor device arrays 2 are separated, which may help to lead out the devices and reduce interference between the devices.

As shown in FIG. 2G, the groove is filled with metal (such as nickel or platinum) through an ALD (atomic layer deposition) or PVD (physical vapor deposition) process. After the silicide 5 is formed by annealing, the metal is removed. During this process, in each three-dimensional semiconductor device array 2, the end face of the source/drain layer 22 adjacent to the isolation groove 3 is metallized. Further, as shown in FIG. 2H, silicon dioxide is deposited on the wafer, so as to form a dielectric isolation layer 6 which covers the contact region and an upper surface of each three-dimensional semiconductor device array 2, as well as each isolation groove 3. An upper surface of the dielectric isolation layer 6 is flattened by chemical mechanical polishing. FIG. 2I shows a top view after the dielectric isolation layer 6 is filled, where the contact regions of the respective three-dimensional semiconductor device arrays 2 are shown.

FIG. 2H schematically shows a sectional view of a manufactured contact region in CC′ direction. The device layers located at opposite ends of each three-dimensional semiconductor device array 2 are etched downwards from the dielectric isolation layer 6, so as to form the staircase like contact region at the source/drain layers 22. As shown in FIG. 2K, silicon dioxide is filled above the contact regions and then flattened by chemical mechanical polishing. A plurality of contact holes 7 are formed by etching downwards in the vertical direction, and each contact hole 7 extends to a contact region of one source/drain layer 22. At this point, the manufacturing of the semiconductor device with decreased source and drain resistance is completed.

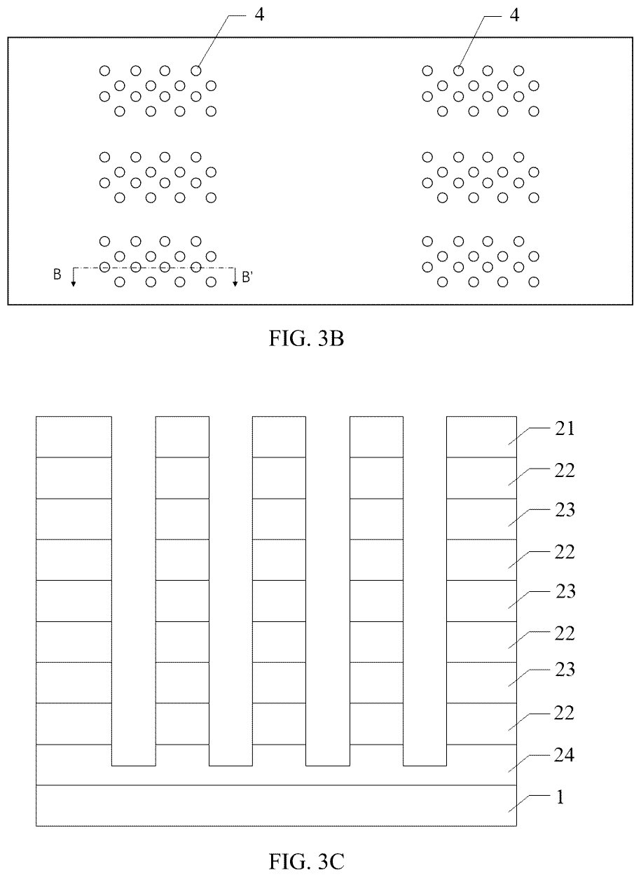

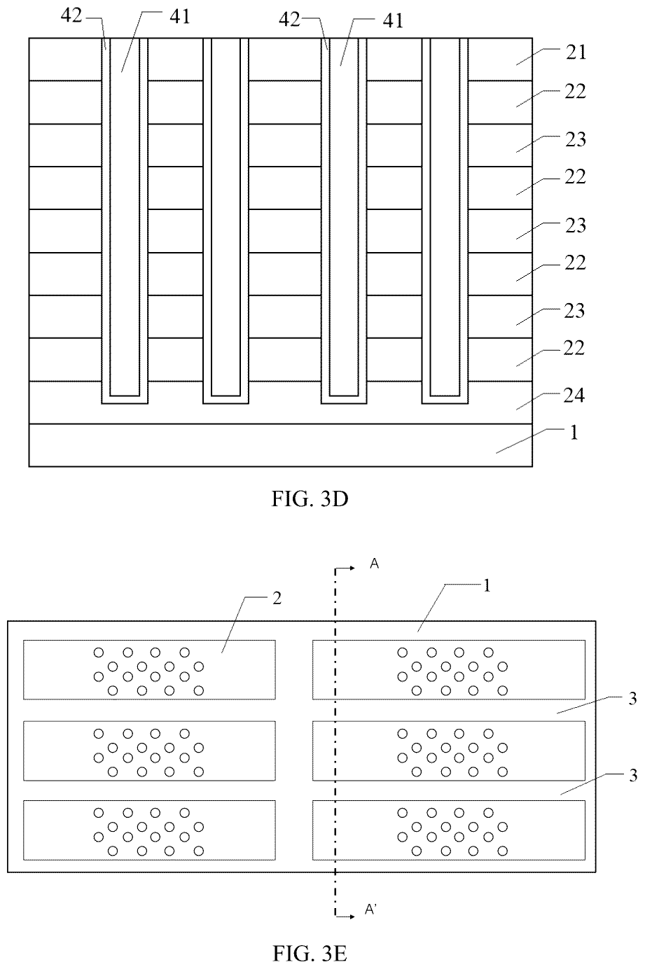

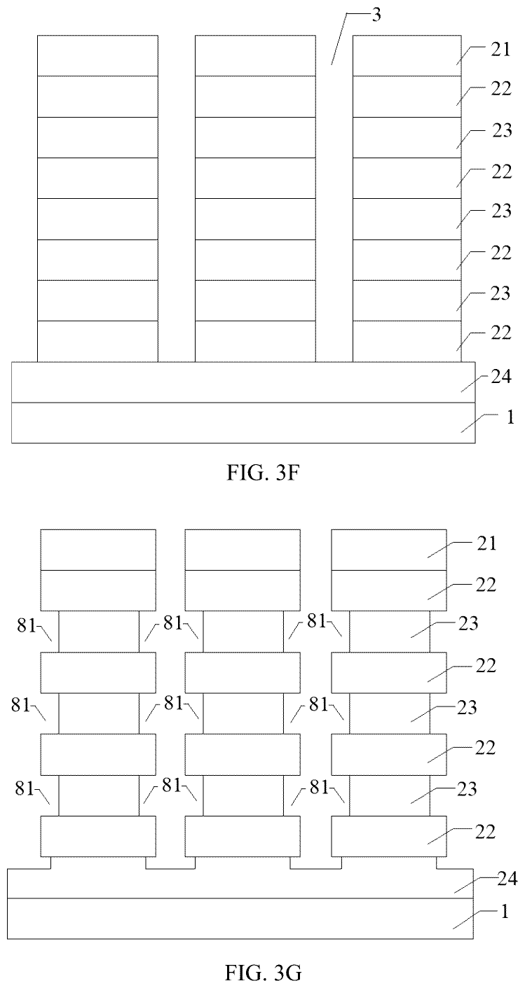

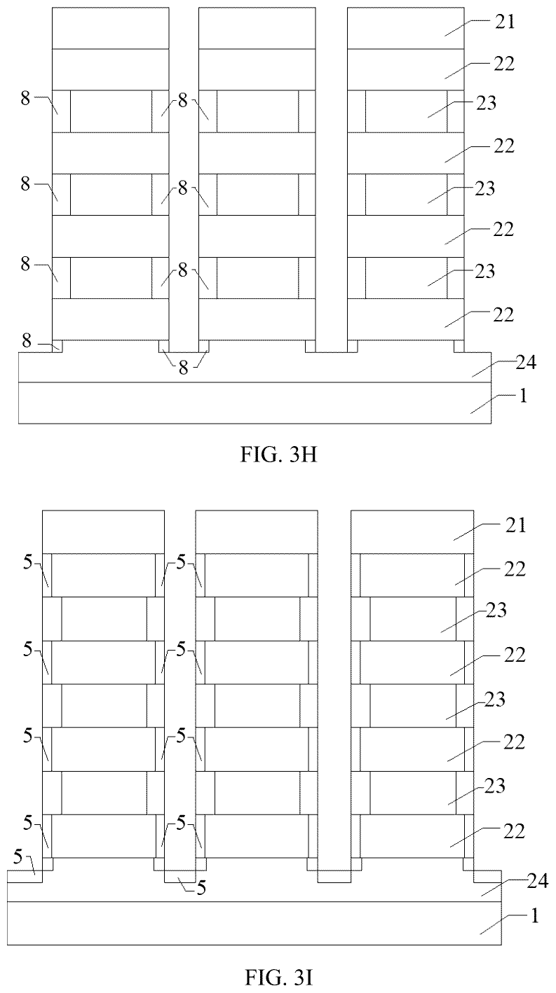

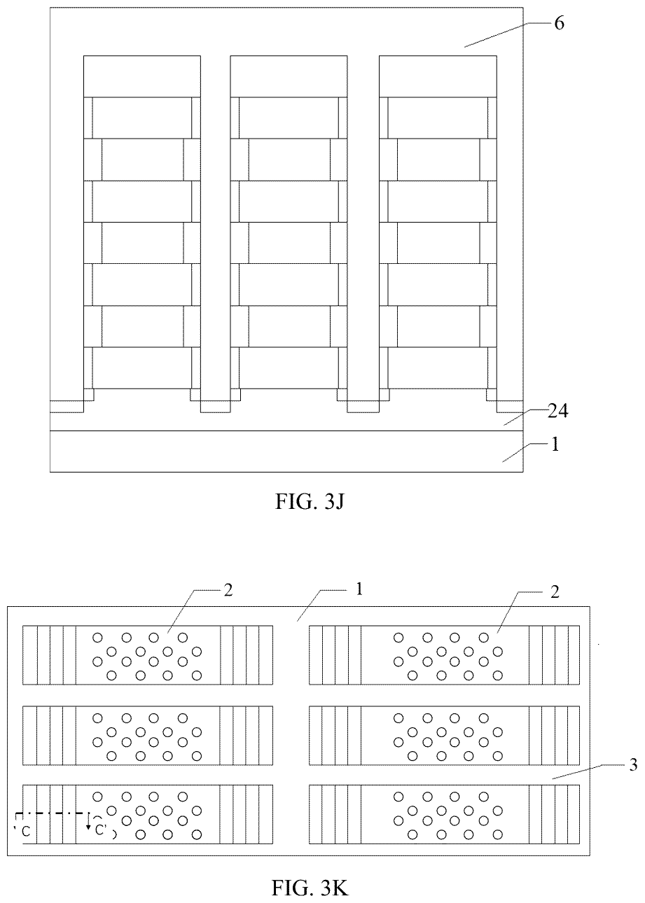

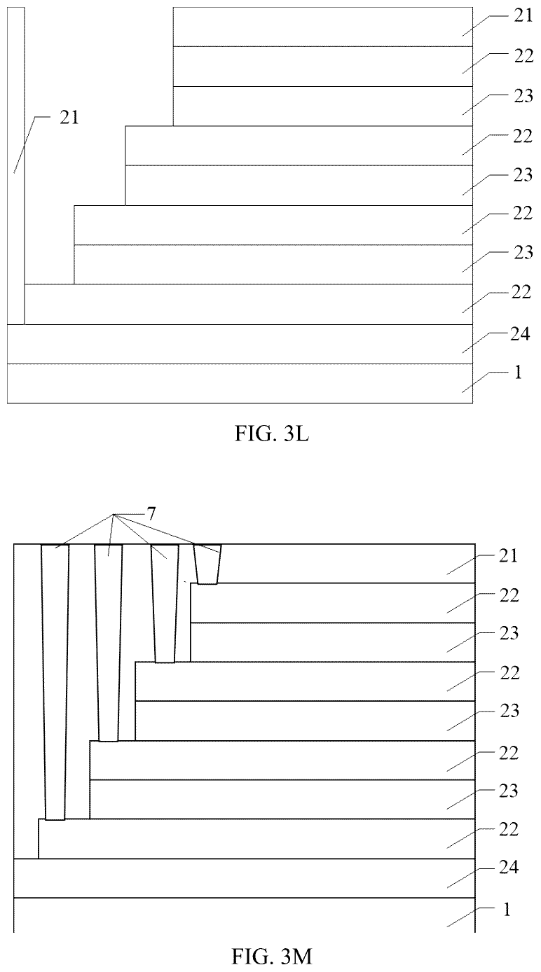

A third embodiment of the present disclosure provides another semiconductor device with decreased source and drain resistance, specific structures of which are schematically shown in FIGS. 3A to 3M, where a manufacturing process of the semiconductor device is also represented.

As shown in FIG. 3A, in the third embodiment of the present disclosure, a plurality of device layers are grown on the substrate 1. In these device layers, the source/drain layers 22 are made of a heavily doped silicon material, the channel layer 23 is made of a silicon germanium material, and the lower source/drain layer 22, the channel layer 23 and the upper source/drain layer 22 are stacked sequentially from bottom to top. The lower source/drain layer 22 of an upper device layer and the upper source/drain layer 22 of a lower device layer which is adjacent to the upper device layer may be the same source/drain layer. By sharing the same source/drain layer, a size of the device may be reduced and the manufacturing process may be simplified. A top of a top device layer in the three-dimensional semiconductor device array 2 is provided with a silicon dioxide isolation layer, and an upper surface of the substrate 1 is provided with a P-type lightly silicon germanium layer 24. FIG. 3A merely schematically shows three device layers stacked together, however, in practical operations, device layers may be stacked infinitely upwards until the techniques cannot support it (one device layer is defined by two adjacent layers of polysilicon). In this example, the device manufactured may be an NMOS device, and this method may also be used to form a PMOS device or an NOR flash. A thickness of doped polysilicon may be in a range of 10 nm to 500 nm, and a thickness of silicon dioxide may be in a range of 5 nm to 500 nm.

As shown in FIG. 3B, the respective device layers are penetrated in a vertical direction perpendicular to the substrate 1, so as to form a plurality of gate holes. Gate stacks 4 are formed in the gate holes, and the gate stacks 4 are arranged in an array. The gate stack 4 includes a gate material 41, and a gate dielectric layer 42 provided between the gate material 41 and the device layer. A device unit is defined at an intersection of the gate stack 4 and the device layer. The gate material 41 may include a conductor material and a semiconductor material.

FIG. 3C shows a sectional view of an array of gate stacks 4 shown in FIG. 3B in BB′ direction. The respective device layers are penetrated in the vertical direction to form the plurality of gate holes. The etching of the gate holes stops when reaching a silicon germanium layer 24 at the bottom.

As shown in FIG. 3D, a gate dielectric layer 42 is deposited in the gate hole, then a gate material 41 is deposited in the gate hole, and a top of the device is flattened by chemical mechanical polishing. A bottom of the gate stack 4 is in the silicon germanium layer 24 which is at the bottom of the three-dimensional semiconductor device array 2.

As shown in FIG. 3E, after the manufacturing of the array of the gate stacks 4 is completed, the device layers are etched in the vertical direction perpendicular to the substrate 1, so as to form the isolation groove 3 and the plurality of three-dimensional semiconductor device arrays 2 which are separated by the isolation groove 3. FIG. 3F schematically shows a sectional view in AA′ direction after etching out the isolation groove 3, and it may be seen that the etching of the isolation groove 3 stops when reaching the silicon germanium layer 24.

As shown in FIG. 3G, the sidewall of the channel layer 23 adjacent to the isolation groove 3 is selectively etched by a certain depth, so as to form a dielectric inner spacer recess 81. As shown in FIG. 3H, the dielectric is deposited on opposite sides of the channel layer 23, and an anisotropic etching is performed, so as to form a dielectric inner spacer 8. A material of the dielectric inner spacer 8 may contain silicon nitride, etc.

As shown in FIG. 3I, the groove is filled with metal (such as nickel or platinum) through the ALD or PVD process. After the silicide 5 is formed by annealing, the metal is removed. During this process, in each three-dimensional semiconductor device array 2, end faces of the source/drain layers 22 adjacent to the isolation groove 3 are metallized. Further, as shown in FIG. 3J, silicon dioxide is filled on the substrate 1, so as to form a dielectric isolation layer 6 which covers the contact region and an upper surface of each three-dimensional semiconductor device array 2, as well as each isolation groove 3. An upper surface of the dielectric isolation layer 6 is flattened by chemical mechanical polishing. FIG. 3K shows a top view after the dielectric isolation layer 6 is filled, where the contact regions of the respective three-dimensional semiconductor device arrays 2 are shown.

FIG. 3L schematically shows a sectional view of a manufactured contact region in CC′ direction. The device layers located at opposite ends of each three-dimensional semiconductor device array 2 are etched downwards from the dielectric isolation layer 6, so as to form the staircase like contact region at the source/drain layers 22. As shown in FIG. 3M, silicon dioxide is filled above the contact regions and then flattened by chemical mechanical polishing. A plurality of contact holes 7 are formed by etching downwards in the vertical direction, and each contact hole 7 extends to a contact region of one source/drain layer 22. At this point, the manufacturing of the semiconductor device with decreased source and drain resistance is completed.

At least one of the above-mentioned technical solutions in the embodiments of the present disclosure may achieve the following beneficial effects.

The semiconductor device with decreased source and drain resistance provided in the present disclosure proposes to reduce a source and drain resistance of a device, increase a turn-on current of the device and enhance consistency of devices in the array by forming a silicide on sidewalls.

Those skilled in the art may understand that the features recorded in the various embodiments and/or claims of the present disclosure may be combined or integrated in a plurality of ways, even if such combinations or integrations are not explicitly recorded in the present disclosure. Specifically, without departing from the spirit and teachings of the present disclosure, the features recorded in the various embodiments and/or claims of the present disclosure may be combined and/or integrated in a plurality of ways. All these combinations and/or integrations fall within the scope of the present disclosure.

Although the present disclosure has been illustrated and described with reference to specific exemplary embodiments of the present disclosure, those skilled in the art should understand that various changes in form and details may be made to the present disclosure without departing from the spirit and scope of the present disclosure defined by the accompanying claims and their equivalents. Therefore, the scope of the present disclosure should not be limited to the aforementioned embodiments, but should be determined not only by the accompanying claims, but also by their equivalents.

What is claimed is:

1. A semiconductor device with decreased source and drain resistance, comprising:
a substrate; and
a plurality of three-dimensional semiconductor device arrays,
wherein the three-dimensional semiconductor device arrays are provided on the substrate, and the three-dimensional semiconductor device arrays are separated by isolation grooves;
wherein each of the three-dimensional semiconductor device arrays comprises a plurality of device layers in a vertical direction, each of the device layers comprises a stack of a source/drain layer, a channel layer and a source/drain layer, and an end face of the source/drain layer adjacent to the isolation groove is metallized to form a silicide; and
wherein the three-dimensional semiconductor device array further comprises a plurality of gate stacks arranged in an array, the gate stack penetrates each of the device layers in the vertical direction and comprises a gate material and a gate dielectric layer provided between the gate material and the device layer, and a device unit is defined at an intersection of the gate stack and the device layer.

2. The semiconductor device with decreased source and drain resistance according to claim 1, wherein the source/drain layer and the channel layer in each of the device layers extend in a direction in which the isolation groove extends, and a staircase like contact region is formed at the source/drain layer.

3. The semiconductor device with decreased source and drain resistance according to claim 2, wherein a silicon dioxide is deposited on the three-dimensional semiconductor device array to form a dielectric isolation layer which covers a contact region and an upper surface of the three-dimensional semiconductor device array as well as each isolation groove, and an upper surface of the dielectric isolation layer is flattened.

4. The semiconductor device with decreased source and drain resistance according to claim 3, wherein vertically etching is performed downwards from the upper surface of the dielectric isolation layer to form a plurality of contact holes, and each of the contact holes extends to the contact region of the source/drain layer.

5. The semiconductor device with decreased source and drain resistance according to claim 1, wherein a lower source/drain layer in an upper device layer and an upper source/drain layer in a lower device layer adjacent to the upper device layer are the same source/drain layer.

6. The semiconductor device with decreased source and drain resistance according to claim 1, wherein a silicon dioxide isolation layer is provided between two source/drain layers of each device layer and at a bottom of the three-dimensional semiconductor device array;
wherein a bottom of the gate stack is located in the silicon dioxide isolation layer at the bottom of the three-dimensional semiconductor device array; and
wherein the channel layer is provided between the gate dielectric layer and a structure formed by the two source/drain layers and the silicon dioxide isolation layer.

7. The semiconductor device with decreased source and drain resistance according to claim 6, wherein each of the source/drain layer and the channel layer is made of a doped polycrystalline silicon material.

8. The semiconductor device with decreased source and drain resistance according to claim 1, wherein an upper surface of the substrate is provided with a silicon germanium layer;
wherein a bottom of the gate stack is located in the silicon germanium layer;
wherein the source/drain layer, the channel layer and the source/drain layer in the device layer are stacked sequentially from bottom to top;
wherein a bottom of the isolation groove is located in the silicon germanium layer; and
wherein a dielectric inner spacer is formed at each of an end face of the channel layer adjacent to the isolation groove and an end face of the silicon germanium layer adjacent to the isolation groove.

9. The semiconductor device with decreased source and drain resistance according to claim 8, wherein the source/drain layer is made of a heavily doped silicon material, and the channel layer is made of a silicon germanium material.

10. A manufacturing method, comprising:
growing a plurality of device layers on a substrate, wherein each of the device layers comprises a stack of a source/drain layer, a channel layer and a source/drain layer;
forming a plurality of gate holes penetrating each of the device layers in a vertical direction perpendicular to the substrate, and forming gate stacks in the gate holes, the gate stacks being arranged in an array, wherein the gate stack comprises a gate material and a gate dielectric layer provided between the gate material and the device layer, and a device unit is defined at an intersection of the gate stack and the device layer;
etching the device layer in the vertical direction perpendicular to the substrate, so as to form isolation grooves and a plurality of three-dimensional semiconductor device arrays separated by the isolation grooves; and
metallizing an end face of the source/drain layer in each of the three-dimensional semiconductor device arrays adjacent to the isolation groove to form a silicide.
